(19) United States
(12) Patent Application Publication
(10) Pub. No.: US 2010/0120175 A1
(43) Pub. Date: May 13, 2010

(54) SENSOR DOUBLE PATTERNING METHODS

(75) Inventors: Andrew Habermas, Bloomington, MN (US); Paul Anderson, Eden Prairie, MN (US)

Correspondence Address: CAMPBELL NELSON WHIPPS, LLC, HISTORIC HAMM BUILDING, 408 SAINT PETER STREET, SUITE 240, ST. PAUL, MN, 55102, US

(73) Assignee: SEAGATE TECHNOLOGY LLC, Scotts Valley, CA (US)

(21) Appl. No.: 12/339,590

(22) Filed: Dec. 19, 2008

Related U.S. Application Data
(60) Provisional application No. 61/112,262, filed on Nov. 7, 2008.

(51) Int. Cl. H01L 21/306; H01L 21/34

(52) U.S. Cl. 438/3; 438/689; 257/E21.215; 257/E21.459

(57) ABSTRACT

A method of making a memory cell or magnetic element by double patterning. The method includes providing a starting stack having a first area, masking a portion of the first area of the starting stack resulting in a first masked portion and a first unmasked portion. Then, removing the first unmasked portion of the starting stack to provide a second area. A portion of this second area is masked, resulting in a second masked portion and a second unmasked portion. The method also includes removing the second unmasked portion to provide a third area, with the finished cell or element being the third area.

### RELATED APPLICATIONS

This application claims priority to U.S. provisional patent application No. 61/112,262, filed on Nov. 7, 2008 and titled “Sensor Double Patterning Method”. The entire disclosure of application No. 61/112,262 is incorporated herein by reference.

### BACKGROUND

Solid state memory devices, which include non-volatile memory devices such as resistive memory and magnetic memory, involves detection of bits based on a change in resistance state or in magnetization orientation, respectively. Controlling the resistance change or magnetization change to make it less variable or more reproducible, i.e., have a constant or narrow distribution, can provide a more reliable product. At least because of their small size, it is desirous to use solid state memory elements in many applications.

One of the key challenges in the manufacturing of solid-state memory devices involves the device patterning. In many embodiments, the size of these devices is significantly less than the wavelength of light (193 nm) conventionally used to transfer the desired pattern from the mask to photoresist to form the eventual size and shape of the device. Furthermore, localized shape control (such as the sharpness of corners) is traditionally degraded due to light diffraction from mask to resist, and again degraded/rounded due to etch effects.

As the size of solid state memory devices and magnetic sensing devices continues to decrease, better fabrication methods are needed.

### BRIEF SUMMARY

The present disclosure relates to methods of making magnetic sensors and memory cells, such as magnetic tunnel junction cells and other cells for spin torque random access memory (ST RAM), phase change memory cells (PC RAM), and cells for resistive random access memory (RRAM). The methods include sequentially double patterning a desired area to obtain a sensor or cell having better features.

In one particular embodiment, this disclosure provides method of making a magnetic cell by double patterning. The method includes providing a magnetic starting stack having a first area, masking a portion of the first area of the starting stack resulting in a first masked portion and a first unmasked portion. Then, removing the first unmasked portion of the starting stack to provide a second area. A portion of this second area is masked, resulting in a second masked portion and a second unmasked portion. The method also includes removing the second unmasked portion to provide a third area, with the magnetic cell being the third area.

These and various other features and advantages will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings, in which:

FIG. 1 is a cross-sectional schematic diagram of an illustrative magnetic element;

FIG. 2 is a cross-section schematic diagram of an illustrative resistive element;

FIGS. 3A through 3D are schematic top views of magnetic elements;

FIG. 4 is a schematic of a first embodiment illustrating double patterning;

FIGS. 5A-5B are schematics of a second embodiment illustrating double patterning;

FIG. 6 is a schematic of a third embodiment illustrating double patterning;

FIGS. 7A-7K are schematic, step wise illustrations of a first method of double patterning a magnetic sensor stack;

FIGS. 8A-8E are schematic, step wise illustrations of an alternate method of double patterning a magnetic sensor stack;

FIGS. 9A-9H are schematic, step wise illustrations of a second method of double patterning a magnetic sensor stack; and

FIGS. 10A-10I are schematic, step wise illustrations of a third method of double patterning a magnetic sensor stack.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

This disclosure is directed to memory cells or any magnetic sensor and methods of making those cells or sensors. The methods provide cells and sensors having precise physical features. In general, the methods include double patterning a magnetic sensor stack, by positioning a mask to cover the desired area of the eventual sensor or cell and additional area, removing the unmasked area, and then removing the mask. A second mask is positioned to cover the desired area of the eventual sensor or cell and additional area, removing the unmasked area, and then removing the mask. Only the area covered by both masks remains.

One particular method described by this disclosure includes providing a magnetic starting stack having a first area, and masking a portion of that first area to result in a first masked portion and a first unmasked portion. The first unmasked portion of the starting stack is removed (e.g., etched) to provide a second area. A portion of this second area is masked, resulting in a second masked portion and a second unmasked portion. This particular method also includes removing (e.g., etching) the second unmasked portion to provide a third area, with the magnetic cell being the third area.

Another particular method described by this disclosure includes providing a starting stack, and applying a first masking pattern on that starting stack, resulting in a first masked portion and a first unmasked portion. The first unmasked portion is removed (e.g., etched). A second masking pattern is applied on the starting stack offset a distance from the first masking pattern, resulting in a second masked portion and a second unmasked portion. This second unmasked portion is removed (e.g., etched). An intersection of the first masked portion and the second masked portion provides a cell area with an aspect ratio and internal angles.

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense. The definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

The present disclosure is directed to methods of making memory cells and sensors, the methods including a two-step patterning technique, which results in improved control of physical shapes, particularly at corners or angled features. While the present disclosure is not so limited, an appreciation of various aspects of the disclosure will be gained through a discussion of the examples provided below.

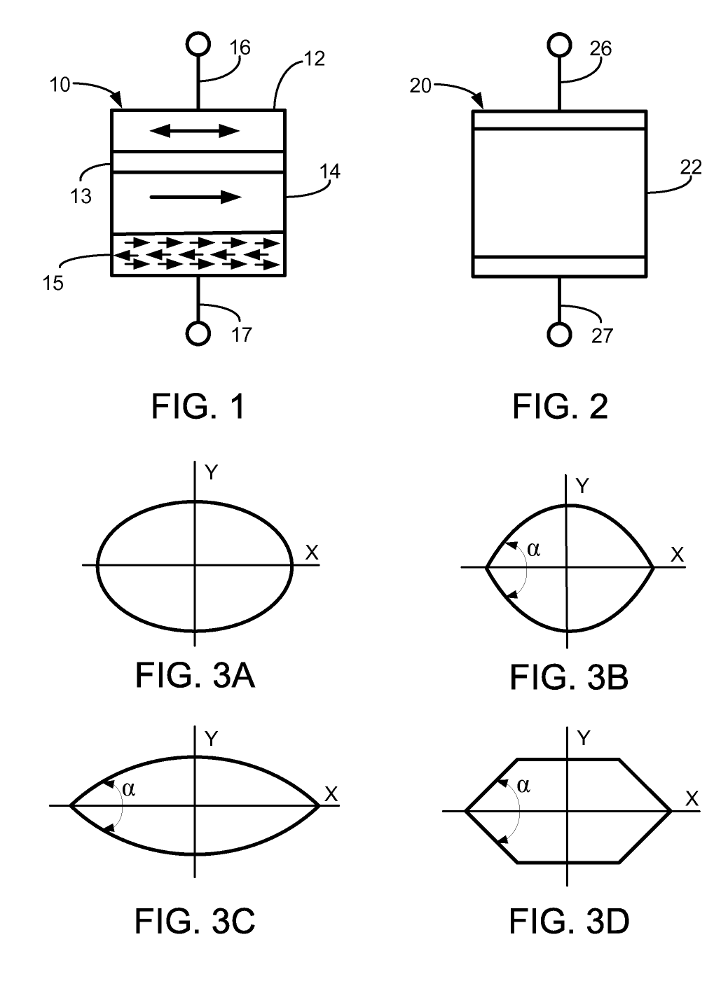

FIG. 1 is a cross-sectional schematic diagram of an illustrative magnetic element or cell. Cell 10 of FIG. 1 may be referred to as a magnetic tunnel junction cell, variable resistive memory cell or variable resistance memory cell or the like. Cell 10 of FIG. 1 is a magnetic element having the magnetization orientations of the ferromagnetic layers illustrated “in-plane”, however, the magnetization orientation could alternately be “out-of-plane”.

In FIG. 1, magnetic cell 10 includes a ferromagnetic free layer 12 and a ferromagnetic reference (i.e., pinned) layer 14. Ferromagnetic free layer 12 and ferromagnetic pinned layer 14 are separated by a non-magnetic spacer layer 13. Proximate ferromagnetic pinned layer 14 is an antiferromagnetic (AFM) pinning layer 15, which pins the magnetization orientation of ferromagnetic pinned layer 14 by exchange bias with the antiferromagnetically ordered material of pinning layer 15. Examples of suitable pinning materials include PtMn, IrMn, and others. Note that other layers, such as seed or capping layers, are not depicted for clarity.

Ferromagnetic layers 12, 14 may be made of any useful ferromagnetic (FM) material such as, for example, Fe, Co or Ni and alloys thereof, such as NiFe and CoFe, and ternary alloys, such as CoFeB. Either or both of free layer 12 and pinned layer 14 may be either a single layer or a synthetic antiferromagnetic (SAF) coupled structure, i.e., two ferromagnetic sublayers separated by a metallic spacer, such as Ru or Cr, with the magnetization orientations of the sublayers in opposite directions to provide a net magnetization. Free layer 12 may be a synthetic ferromagnetic coupled structure, i.e., two ferromagnetic sublayers separated by a metallic spacer, such as Ru or Ta, with the magnetization orientations of the sublayers in parallel directions. Either or both layer 12, 14 are often about 0.1-10 nm thick, depending on the material and the desired resistance and switchability of free layer 12.

If magnetic cell 10 is a magnetic tunnel junction cell, non-magnetic spacer layer 13 is an insulating barrier layer sufficiently thin to allow tunneling of charge carriers between pinned layer 14 and free layer 12. Examples of suitable electrically insulating material include oxides material (e.g., Al₂O₃, TiOₓ or MgO). If magnetic cell 10 is a spin-valve cell, non-magnetic spacer layer 13 is a conductive non-magnetic spacer layer. For either a magnetic tunnel junction cell or a spin-valve, non-magnetic spacer layer 13 could optionally be patterned with free layer 12 or with pinned layer 14, depending on process feasibility and device reliability.

The resistance across magnetic cell 10 is determined by the relative orientation of the magnetization vectors or magnetization orientations of ferromagnetic layers 12, 14. The magnetization direction of ferromagnetic pinned layer 14 is pinned in a predetermined direction by pinning layer 15 while the magnetization direction of ferromagnetic free layer 12 is free to rotate under the influence of spin torque. In FIG. 1, the magnetization orientation of free layer 12 is illustrated as undefined. In some embodiments, magnetic tunnel junction cell 10 is in the low resistance state or “0” data state where the magnetization orientation of free layer 12 is in the same direction or parallel to the magnetization orientation of pinned layer 14. In other embodiments, magnetic tunnel junction cell 10 is in the high resistance state or “1” data state where the magnetization orientation of free layer 12 is in the opposite direction or anti-parallel to the magnetization orientation of pinned layer 14.

Switching the resistance state and hence the data state of magnetic cell 10 via spin-transfer occurs when a current, under the influence of a magnetic layer of magnetic cell 10, becomes spin polarized and imparts a spin torque on free layer 12 of magnetic cell 10. When a sufficient level of polarized current and therefore spin torque is applied to free layer 12, the magnetization orientation of free layer 12 can be changed among different directions and accordingly, magnetic cell 10 can be switched between the parallel state, the anti-parallel state, and other states.

A first electrode 16 is in electrical contact with ferromagnetic free layer 12 and a second electrode 17 is in electrical contact with ferromagnetic pinned layer 14 via pinning layer 15. Electrodes 16, 17 electrically connect ferromagnetic layers 12, 14 to a control circuit providing read and write currents through layers 12, 14.

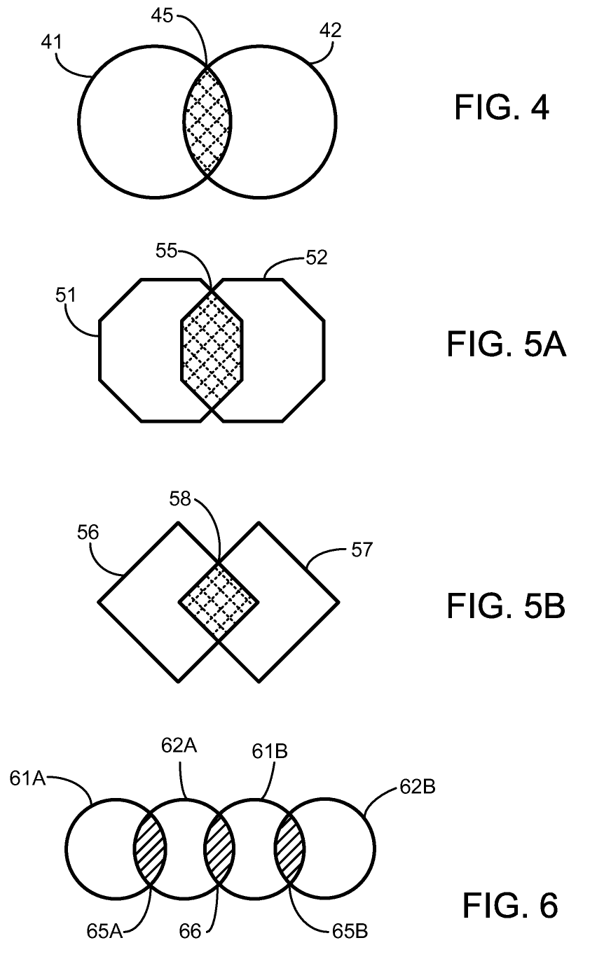

Resistive sensor cell 20 of FIG. 2 has an electrically resistive layer 22. A first electrode 26 is in electrical contact with a first side of layer 22 and a second electrode 27 is in electrical contact with a second side of layer 22. Other layers, such as seed or capping layers, are not depicted for clarity. Electrodes 26, 27 provide a current or voltage through layer 22, in order to alter the resistance of layer 22. The resistance of layer 22 may alter, for example, by the creation of conductive filaments, fibrils or superionic clusters from electrode 26 to electrode 27 through layer 22. Electrodes 26, 27 also electrically connect layer 22 to a control circuit providing read and write currents through layer 22. In some embodiments, resistive cell 20 is in the low resistance state or “0” data state. In other embodiments, resistive cell 20 is in the high resistance state or “1” data state.

The illustrative elements 10, 20 are used to construct a memory device where a data bit is stored in the spin torque memory cell by changing the relative magnetization state of layer 12, with respect to pinned layer 14 or the resistive state of layer 22.

In order for cell 10, 20 to have the characteristics of a non-volatile random access memory, layer 12, 22 exhibits thermal stability against random fluctuations so that the orientation or resistance of layer 12, 22 is changed only when it is controlled to make such a change. This thermal stability can be achieved, for example, via the magnetic anisotropy using different methods, e.g., varying the bit size, shape, and crystalline anisotropy. Additional anisotropy can be obtained through magnetic coupling to other magnetic layers either through exchange or magnetic fields. Generally, the anisotropy causes a soft and hard axis to form in thin magnetic layers. The hard and soft axes are defined by the magnitude of the external energy, usually in the form of a magnetic field, needed to fully rotate (saturate) the direction of the magnetization in that direction, with the hard axis requiring a higher saturation magnetic field.

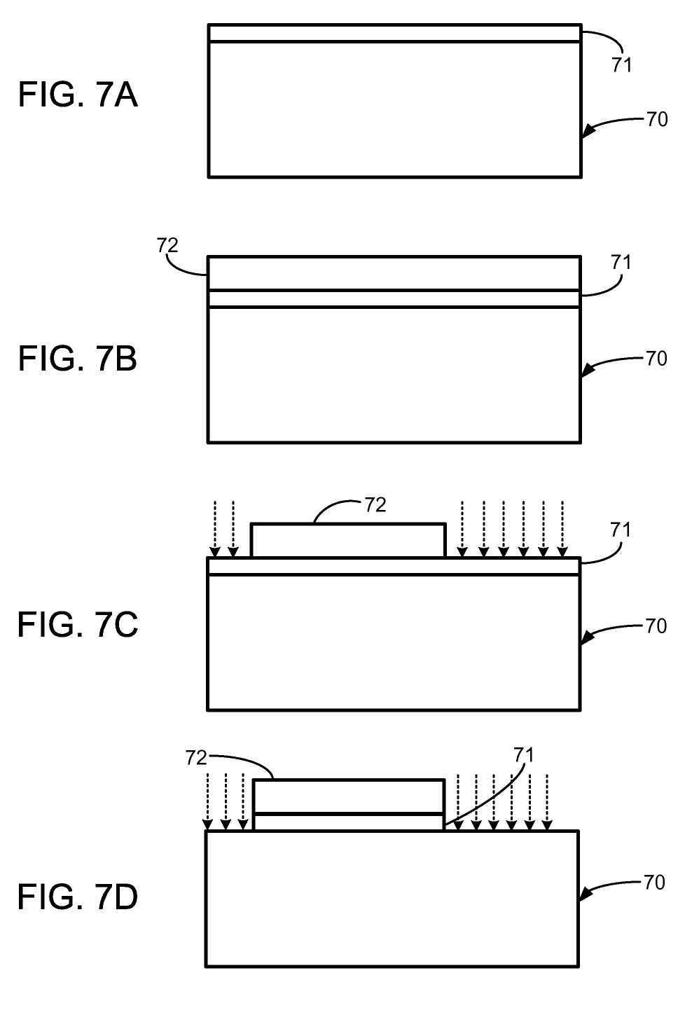

The physical shape of the switchable magnetic layer (e.g., layer 12) affects both the thermal stability of the layer and the overall cell and also affects the current and/or magnetic field needed to switch the magnetization orientation of the magnetic layer. FIGS. 3A through 3D illustrate four different suitable shapes for magnetic layers with switchable magnetization orientation (e.g., layer 12, 22). In most embodiments, the shape of the switchable magnetic layer is the same as the shape of the overall magnetic element or cell (e.g., cell 10, cell 20).

FIG. 3A illustrates an ellipse; FIG. 3B illustrates a first ‘football’ shape; FIG. 3C illustrates a second ‘football’ shape; and FIG. 3D illustrates a distorted hexagon. Each of the shapes of FIGS. 3A through 3D have a long or major axis “X” and a short or minor axis “Y”. The major axis represents the length of the shape, and the minor axis represents the width of the shape. Each shape has an aspect ratio, which is the ratio of the length to the width. The aspect ratio for the shape of FIG. 3A is about 1.5, for FIG. 3B is about 1.3, for FIG. 3C is about 2.5, and for FIG. 3D is about 2.

The ellipse of FIG. 3A has a continuous smooth perimeter, whereas the shapes of FIGS. 3B, 3C and 3D have corners along the major axis having an internal angle of α. The distorted hexagon of FIG. 3D has additional corners, in addition to those along the major axis. Angle α, for an internal corner, is between about 30 and 120 degrees, in some embodiments, about 45 to 90 degrees, or about 45 to 60 degrees. For FIG. 3B α is about 115 degrees, for FIG. 3C α is about 75 degrees and for FIG. 3D α is about 90 degrees.

Each shape (e.g., that of FIG. 3A, 3B, 3C, 3D, etc.) has a critical dimension (CD) that refers generally to a physical size or dimension of a feature, the size or dimension being the one needed to be precisely controlled in order to satisfy cell design requirements. The target CD and its acceptable standard deviation depend entirely on the cell design requirements. In many embodiments, the CD is the smallest feature capable of being manufactured within a controlled standard deviation. In some embodiments, the internal angles along the major axis are the CD of an element. For these cells, it is desired to have precise control over the placement, sharpness, and angle shape of the internal angles in order to obtain a reliable, consistent and reproducible cell or sensor structure.

Shapes having an internal angle, such as those of FIGS. 3B, 3C, 3D are beneficial in some embodiment over shapes without internal angles, such as the ellipse of FIG. 3A. The present disclosure provides various methods for forming memory cells, such as cell 10 and cell 20, having precise angles. The various methods of this disclosure include double patterning an area. The sequential, two-step patterning provides improved control of physical shapes, particularly at corners or angled features.

In general, the methods of double patterning require positioning a mask on a substrate, which covers the desired area of the eventual sensor or cell and additional area, removing the unmasked area of the substrate, and then removing the mask. A second mask is positioned on the substrate, covering the desired area of the eventual sensor or cell and additional area, removing the unmasked area of the substrate, and then removing the mask. Only the area covered by both masks remains.

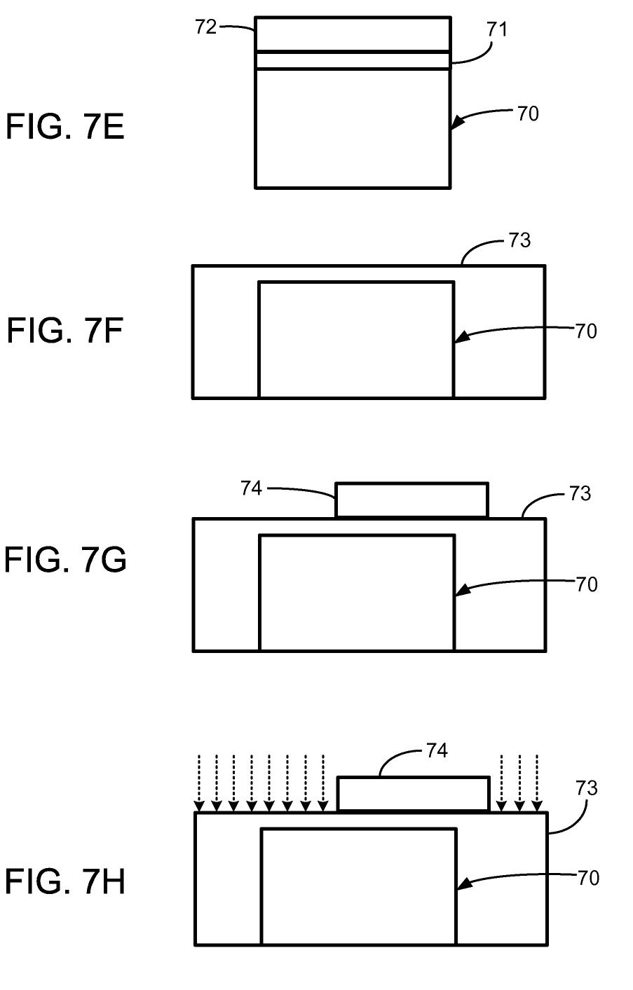

In FIG. 4, a first double patterning scheme is illustrated using shaped patterns that represent the photomasks used during the etching process. Utilizing circle-shaped patterns, two circles are sequentially patterned, with an overlapping area that forms the final sensor or cell pattern. In FIG. 4, a first circular pattern 41 overlaps a second circular pattern 42, to provide an overlap area 45 (shaded area) that has a football-like shape. Overlap area 45 has two sharp, internal corners at each end of its long axis, where pattern 41 and pattern 42 intersect.

The methods that include double patterning result in little or no photo diffraction corner rounding, since the high spatial-frequency of the corner itself is never transmitted through the photomask. Instead, the corner is the result of two overlapped low spatial-frequency patterns (i.e., the two simple (e.g., circular) masks). Additionally, double patterning results in reduced corner rounding due to etch, since the number of available angles for incident ions is reduced.

The method of double patterning with circular masks or patterns also offers two control knobs for controlling the sensor's aspect ratio, which can be done by adjusting the position of either or both patterns 41, 42 or by adjusting the exposure dose used with either or both patterns 41, 42. An increase in the offset between patterns 41, 42 will cause the width of overlap area 45 to decrease (on a percentage basis of nominal) significantly faster than the length of overlap area 45 (on a percentage basis). In other words, n increase in the offset between patterns 41, 42 will cause the aspect ratio to increase (i.e., major axis increases in relation to minor axis), and a decrease in the offset between patterns 41, 42 will cause the aspect ratio to decrease (i.e., major axis decreases in relation to minor axis. A decrease in the exposure dose used for both patterns 41, 42 will also cause the aspect ratio to increase.

Double patterning also provides two control knobs for controlling the sensor's internal angles, which can be done by adjusting the position of either or both patterns 41, 42 or by adjusting the exposure dose used with either or both patterns 41, 42. An increase in the offset between patterns 41, 42 will cause the angles to become more acute (i.e., reduce the angle). A decrease in the exposure dose used for both patterns 41, 42 will also cause the point angles to become more acute.

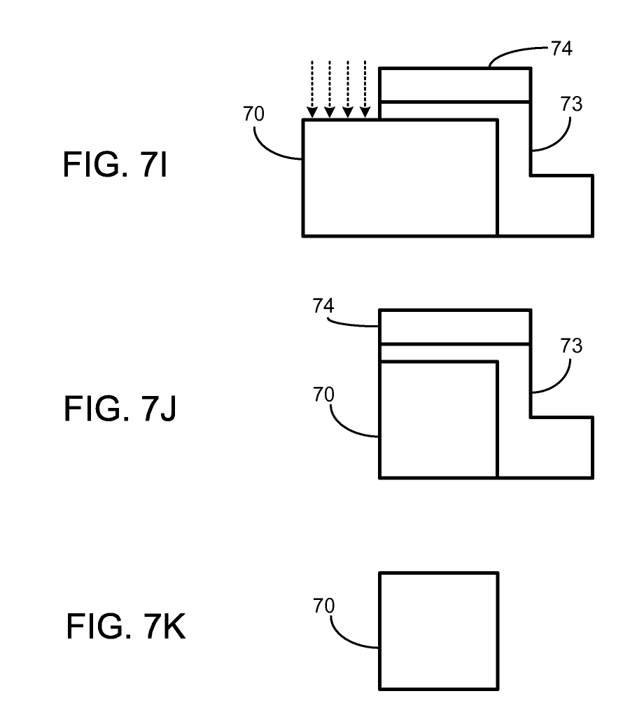

In FIGS. 5A and 5B, a second two-step or double patterning scheme is illustrated using polygonal patterns that represent the photomasks used during the etching process. In FIG. 5A, utilizing octagonal patterns, two octagons are sequentially patterned, with an overlapping area that forms the final sensor or cell pattern. In FIG. 5A, a first octagon pattern 51 overlaps a second octagon pattern 52, to provide an overlap area 55 (shaded area) that has a distorted hexagon shape. Overlap area 55 has two sharp, internal corners along its major axis, where pattern 51 and pattern 52 intersect, and four additional internal corners along its minor axis, two defined by pattern 51 and two defined by pattern 52. In FIG. 5B, utilizing square (diamond) patterns, two diamond are sequentially patterned, with an overlapping area that forms the final sensor or cell pattern. In FIG. 5B, a first diamond pattern 56 overlaps a second diamond pattern 57, to provide an overlap area 58 (shaded area) that has a diamond shape. Overlap area 58 has two sharp, internal corners along its major axis, where pattern 56 and pattern 57 intersect, and two additional internal corners along its minor axis.

The method of double patterning with octagonal and diamond masks provide sharp corners, similar to patterning with circular masks, and also provide a control knob for controlling the sensor's aspect ratio, similar to patterning with circular masks. Double patterning with octagonal masks, however, locks or fixes the internal angles along the major axis, allowing the aspect ratio to be adjusted independently from point angle. An increase in the offset between patterns 51, 52 will cause the aspect ratio to increase (i.e., major axis increases in relation to minor axis), while the point angle remains constant. Conversely, a decrease in the offset between patterns 51, 52 will cause the aspect ratio to decrease (i.e., major axis decreases in relation to minor axis), while the point angle remains constant. Double patterning with diamond masks also locks or fixes the internal angles along the major axis. However, the aspect ratio between the major axis and the minor axis is fixed.

Octagons are one preferred pattern shape because of their geometry which produces acute internal corners on the long or major axis. Other polygons may also be used, and the result may be the same or different than with octagons. For example, squares and rectangles should be oriented so that the corners of the patterns overlap, in order to produce acute internal corners (e.g., be oriented as diamonds). The overlap area may or may not, however, have a definite long or major axis versus short or minor axis. Triangles and pentagons would produce a sharp point at one end of the long or major axis, and a blunt end at the other end of the long or major axis. Hexagons would provide the same geometric benefits as octagons.

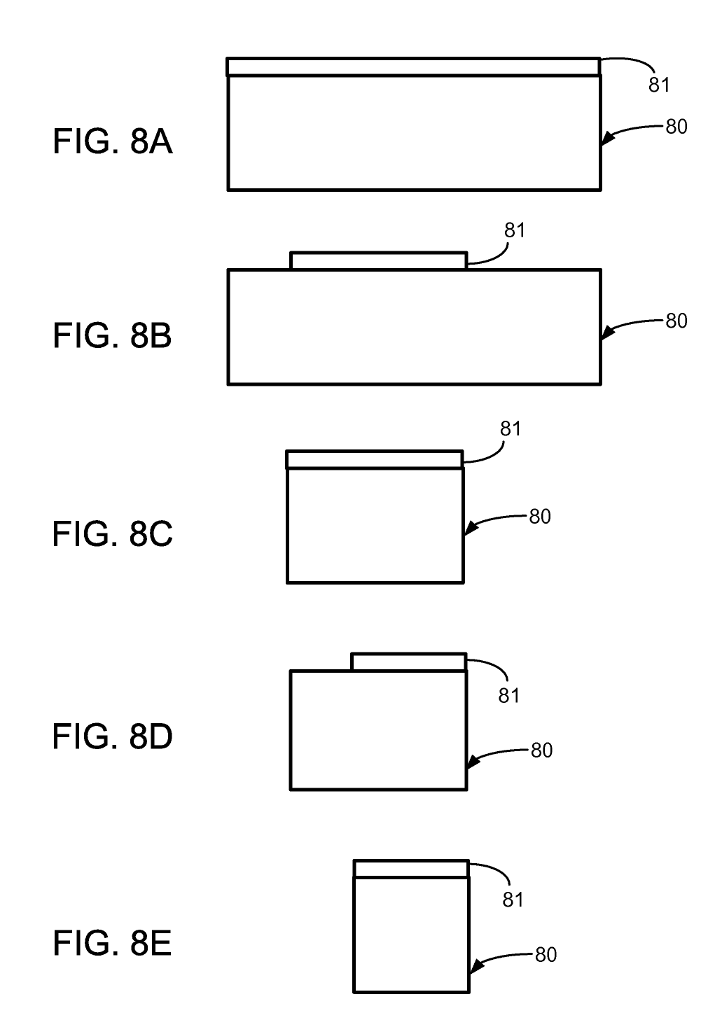

More than two circular patterns 41, 42, octagonal patterns 51, 52, diamond patterns 56, 57 or other polygonal patterns could be used for double patterning processes. FIG. 6 illustrates a two-step or double patterning scheme utilizing more than two patterns. With multiple patterns, the internal patterns utilize both of their edges to define the sensors. FIG. 6 has four patterns 61A, 61B, 62A, 62B shown and three overlap areas 65A, 65B, 66 (shaded areas), which have a football-like shape with two sharp internal corners. During the patterning process, first patterns 61A, 61B would first be used, exposing all areas unshaded thereby. Then, second patterns 62A, 62B would be used, exposing all areas unshaded thereby. Overlap areas 65A, 65B, 66 would remain shaded during both patterning steps and thus form the eventual sensor. Overlap area 65A is formed by pattern 62A overlapping pattern 61A, overlap area 65B is formed by pattern 62B overlapping pattern 61B, and overlap area 66 is formed by pattern 62A overlapping pattern 61B.

Use of both the right and left edges of a pattern does, however, sacrifice one of the two process control knobs that affects the aspect ratio of the sensor. Any shift in a pattern overlay will result in half of the sensors having increased widths and half with decreased widths. To compensate, the exposure dose control knob can be used to adjust the aspect ratio. Using more than two patterns is beneficial, because higher sensor densities can be achieved by using more than two patterns.

The double patterning or two-step patterning, whether with two patterns or more patterns, circular, octagonal or other shape, can be accomplished by several process integration sequences, several of which are briefly explained below. Overall, the magnetic sensors of this disclosure may be made by thin film techniques such as chemical vapor deposition (CVD), physical vapor deposition (PVD), atomic layer deposition (ALD), photolithography, or other thin film deposition techniques, and by wet or dry etching, ion milling, inductive coupled plasma (ICP), reactive ion etching (RIE) or other thin film removal techniques.

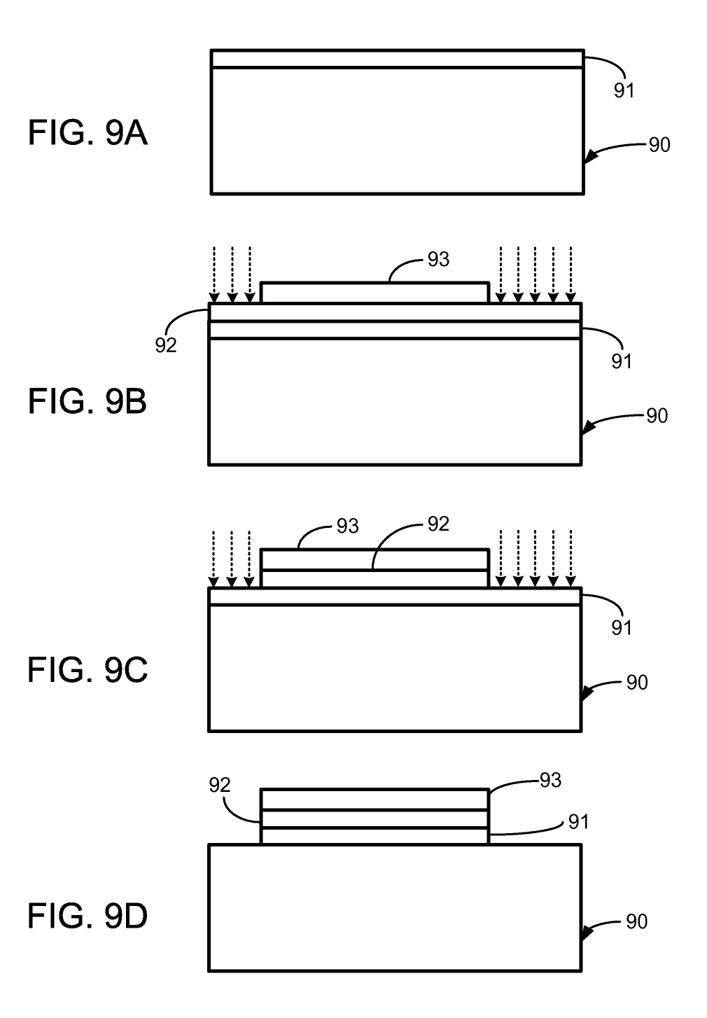

Method 1: In a first method, schematically illustrated in FIGS. 7A-7K, a stack of magnetic sensor material 70 is deposited or otherwise provided in FIG. 7A. Sensor stack 70 may be the layers for a magnetic tunnel junction cell or a magnetic spin-valve cell, as described above in relation to FIGS. 1 and 2, or sensor stack 70 may be materials for other memory cells or sensors. An organic or inorganic bottom antireflective coating (BARC) layer 71 may be applied over sensor stack 70.

In one embodiment, BARC layer 71 (if present) is patterned and etched, using the two-pattern methods of this disclosure. In FIG. 7B, a first photoresist or photomask 72 is applied over BARC layer 71 and a pattern is applied via exposure to light in FIG. 7C. An etch of BARC layer 71 provides the structure of FIG. 7D. The patterned stack 70 is removed (e.g., etched) in FIG. 7D to provide the structure of FIG. 7E. A second BARC layer 73 is applied over magnetic stack 70 in FIG. 7F and over adjacent surfaces. A second photoresist or photomask 74 is applied in FIG. 7G and a pattern is applied via exposure to light in FIG. 7H. In FIG. 7I, BARC layer 73 is etched (it is noted that thicker areas of BARC layer 73 may not be completely removed by this etch) and magnetic stack 70 is etched to remove the unmasked portions, resulting in the structure of FIG. 7J. Photoresist layer 74 and BARC layer 73 are removed from FIG. 7J to leave sensor stack 70 shaped as desired in FIG. 7K. Any of the etch of BARC layers 71, 73 and the etch of sensor stack 70 may be done by thin-film techniques, such as inductive coupled plasma/reactive ion etch (ICP/RIE) or ion milling, for example.

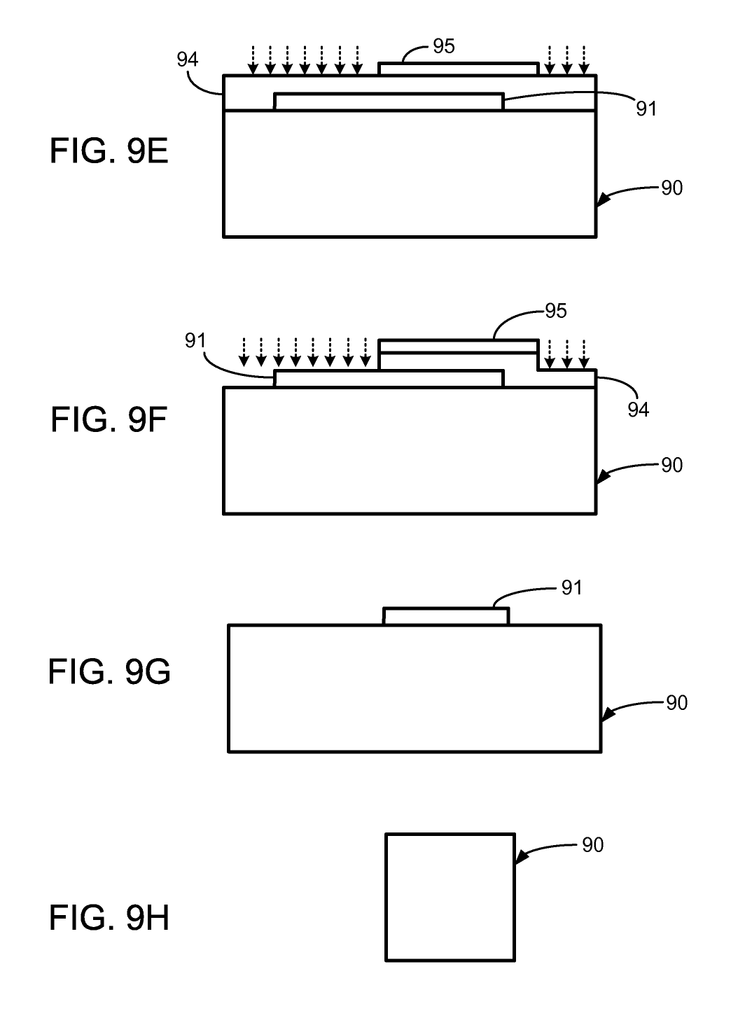

In an alternate embodiment, schematically illustrated in FIGS. 8A-8E, a stack of magnetic sensor material 80 and optional BARC layer 81 (e.g., an inorganic BARC material) are deposited or otherwise provided in FIG. 8A. The first pattern is patterned and etched into BARC layer 81 (if present) in FIG. 8B and then into sensor stack 80 below in FIG. 8C; the photoresist or photomask is not illustrated in these figures; one skilled in the art, and from the previous method discussion, would understand the use of a photoresist or photomask layer. After etching the first pattern, the second pattern is patterned and etched into BARC layer 81 (if present) in FIG. 8D and then into sensor stack 80 in FIG. 8E. BARC layer 81 is removed to leave magnetic sensor stack 80 shaped as desired. Again, either or both the BARC layer etch and the sensor stack etch may be done by thin-film techniques, such as inductive coupled plasma/reactive ion etch (ICP/RIE) or ion milling, for example. One benefit of this alternative method is in having one BARC layer with two purposes—as an anti-reflection for photolithography, and as a hardmask for the magnetic stack etch. A possible, potential disadvantage is that the second photolithography patterning step may expose some areas over the BARC layer and some areas not over the BARC layer, causing potential reflectivity/patterning issues.

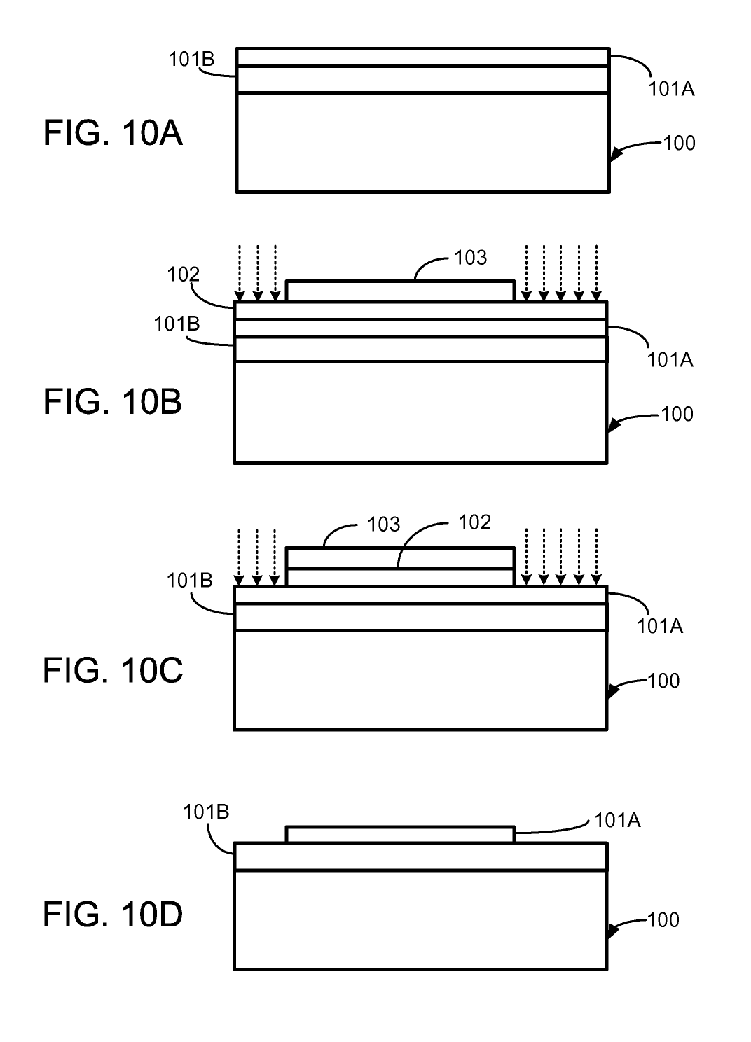

Method 2: A second method for utilizing double patterning is similar to Method 1 described above, except for the following differences. Method 2 is schematically illustrated in FIGS. 9A-9H. After depositing or otherwise providing the stack of sensor material 90 in FIG. 9A, a hardmask 91 (e.g., silicon nitride, silicon oxide, silicon oxy-nitride, alumina, etc.) is applied (e.g., deposited) onto sensor stack 90. Any optional BARC layer 92 would be provided over this hardmask 91. After patterning with a photoresist 93 in FIG. 9B and etching any BARC layer 92 in FIG. 9C, a hardmask etch would be done (from FIG. 9C to FIG. 9D), either stopping at the sensor stack material or continuing with a complete etch through the sensor stack material. In FIG. 9D, the hardmask etch stopped at stack 90. The method continues in FIG. 9E where a second BARC layer 94 and a second photoresist or photomask 95 are applied. BARC layer 94 is eteched in FIG. In FIG. 9G, photoresist 95 and BARC layer 94 have been removed and magnetic stack 90 is etched to remove the unmasked portions, resulting in magnetic stack structure 90 of FIG. 9H.

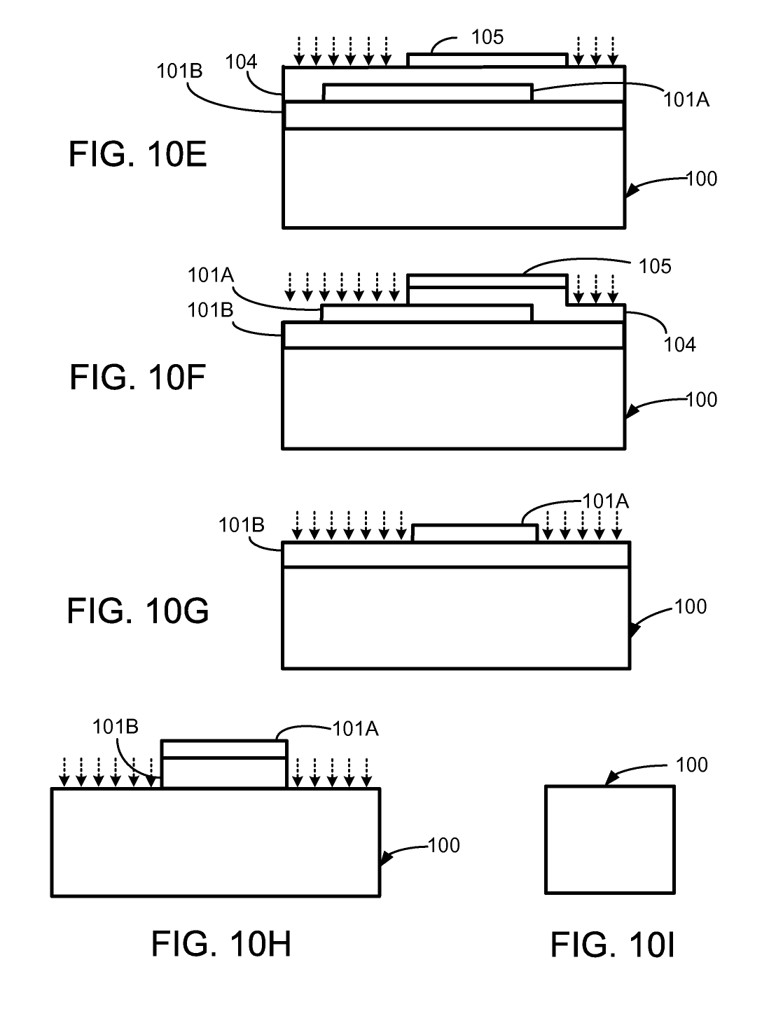

Method 3: A third method for utilizing double patterning, schematically illustrated in FIGS. 10A-10I, is similar to Method 1 described above, except for the following differences. After depositing or otherwise providing the stack of sensor material 100, two hardmask films 101A, 101B are applied (e.g., deposited) in FIG. 10A. Examples of the two hardmask films include amorphous carbon+silicon oxy-nitride and amorphous carbon+thin metal. In some embodiments, first hardmask 101A is relatively thin (e.g., about 25-100 Å), and second hardmask 101B is thicker (e.g., about 500-2000 Å). Any optional BARC layer 102 would be provided over hardmask 101A in FIG. 10B. After patterning with photoresist 103 in FIG. 10B and etching any BARC layer 102 in FIG. 10C, the first pattern would be formed on hardmask 101A and an etching step (e.g., ion mill, reactive ion, wet, etc) would penetrate the thin first hardmask 101A, stopping on the thicker second hardmask layer 101B in FIG. 10D.

A second photoresist pattern 105 is exposed and etched into this same thin first hardmask 101A. Any optional BARC layer 104 would be provided between hardmask 101A and photoresist 105. The second photo pattern 105 is etched into first hardmask 101A as illustrated in FIGS. 10E and 10F and described previously, and then is transferred via an ICP/RIE etch into second hardmask 101B in FIG. 10G, followed by another ICP/RIE/mill etch to transfer the second hardmask 101B into the sensor material 100 in FIG. 10H, resulting in sensor stack 100 in FIG. 10I.

Because first hardmask 101A is relatively thin, the topography effects of the first etched pattern upon the second photo exposure's focus margin are relatively low and generally within the process window control. Transferring this thin pattern into the second thicker hardmask more process margin during the sensor etch.

Method 4: A fourth method for utilizing double patterning is similar to Method 1 described above, except for the following differences. After depositing or otherwise providing the stack of sensor material, a top lead metal deposition is introduced over the sensor stack. The two etches following the two photo steps could either simultaneously penetrate through both the top lead metal and sensor material, or could both stop on the top layer of the sensor material leaving the sensor material to be etched at an immediately subsequent step.

Method 5: A fifth method for utilizing double patterning is similar to Method 3 described above, except for the following differences. After depositing or otherwise providing the stack of sensor material, instead of applied the two hardmasks of Method 3, a single hardmask layer (e.g., silicon nitride, silicon oxide, silicon oxy-nitride, alumina, amorphous carbon+silicon oxy-nitride, amorphous carbon+thin metal, etc.) is provided (e.g., deposited). Directly after the double patterning, a hardmask etch would be done, either stopping at the top lead metal or continuing through to stop on the sensor material.

For each of the methods described, the BARC layer may be a carbon (e.g., amorphous carbon) or organic non-photosensitive layer. In some embodiments, an intermediate layer of tantalum (Ta) or alumina (Al₂O₃) may be positioned over the BARC layer, so that the intermediate layer positioned between the BARC layer and the photoresist or photomask layer. This intermediate layer may have a thickness of about 20-100 Å, in some embodiments about 50 Å. By utilizing an intermediate layer, Method 1, for example, would be a three-step double patterning method (i.e., double patterning the intermediate layer, double patterning the BARC layer, and then double patterning the magnetic sensor stack layer). Utilizing a three-step method even more precisely defines the sharp corners of the final magnetic sensor stack. Additionally, utilizing a thin intermediate layer decreases defects due to profile issues ad reflectivity issues. After the double-patterning, by any of the methods described, the intermediate layer is removed.

In general, the methods of two-step patterning require positioning a mask on a substrate, which covers the desired area of the eventual sensor or cell and additional area, removing the unmasked area of the substrate, and then removing the mask. A second mask is positioned on the substrate, covering the desired area of the eventual sensor or cell and additional area, removing the unmasked area of the substrate, and then removing the mask. Only the area covered by both masks remains.

By using double patterning, a more precisely shaped and reproducible magnetic sensor can be obtained. With double patterning, the relative position of the two patterns can be adjusted to adjust the aspect ratio of the sensor. With circular patterns, the relative position of the two patterns can be adjusted to adjust the internal angles of the sensor. Conversely, with polygonal patterns, such as octagons, the relative position of the two patterns does not affect the internal angles of the sensor.

Thus, embodiments of the SENSOR DOUBLE PATTERNING METHODS are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation, and the present invention is limited only by the claims that follow.

What is claimed is:

1. A method of making a memory cell, comprising:
providing a starting stack having a first area;
masking a portion of the first area of the starting stack, resulting in a first masked portion and a first unmasked portion;
removing the first unmasked portion of the starting stack to provide a second area;
masking a portion of the second area, resulting in a second masked portion and a second unmasked portion; and
removing the second unmasked portion to provide a third area, the memory cell comprising the third area.

2. The method of claim 1 wherein removing the second unmasked portion to provide a third area comprises providing the third area with an aspect ratio and internal angles.

3. The method of claim 2 wherein the first masked portion is circular and the second masked portion is circular.

4. The method of claim 3 further comprising increasing an offset distance between the first circular masked portion and the second circular masked portion to increase the aspect ratio and decrease the internal angles.

5. The method of claim 3 further comprising decreasing an offset distance between the first circular masked portion and the second circular masked portion to decrease the aspect ratio and increase the internal angles.

6. The method of claim 2 wherein the first masked portion is octagonal and the second masked portion is octagonal.

7. The method of claim 6 further comprising increasing an offset distance between the first octagonal masked portion and the second octagonal masked portion to increase the aspect ratio.

8. The method of claim 6 further comprising decreasing an offset distance between the first octagonal masked portion and the second octagonal masked portion to decrease the aspect ratio.

9. The method of claim 1 wherein providing a starting stack comprises providing a stack of a first ferromagnetic layer having a pinned magnetization orientation and a second ferromagnetic layer having a switchable magnetization orientation, the first ferromagnetic layer and the second ferromagnetic layer separated by a non-magnetic spacer layer.

10. A method of making a magnetic element, comprising:
providing a starting stack;
applying a first masking pattern on the starting stack, resulting in a first masked portion and a first unmasked portion;
removing the first unmasked portion;
applying a second masking pattern on the starting stack offset a distance from the first masking pattern, resulting in a second masked portion and a second unmasked portion;
removing the second unmasked portion;
wherein an intersection of the first masked portion and the second masked portion provides a element area with an aspect ratio and internal angles.

11. The method of claim 10 wherein applying a first masking pattern and applying a second masking pattern comprises applying the same mask twice.

12. The method of claim 10 wherein applying a first masking pattern and applying a second masking pattern comprises applying a first circular masking pattern and applying a second circular masking pattern.

13. The method of claim 12 further comprising increasing the offset distance between the second masking pattern and the first masking pattern to increase the aspect ratio and decrease the internal angles.

14. The method of claim 12 further comprising decreasing the offset distance between the second masking pattern and the first masking pattern to decrease the aspect ratio and increase the internal angles.

15. The method of claim 10 wherein applying a first masking pattern and applying a second masking pattern comprises applying a first polygonal masking pattern and applying a second polygonal masking pattern.

16. The method of claim 15 further comprising increasing the offset distance between the second masking pattern and the first masking pattern to increase the aspect ratio.

17. The method of claim 15 further comprising decreasing the offset distance between the second masking pattern and the first masking pattern to decrease the aspect ratio.

18. The method of claim 15 wherein applying a first polygonal masking pattern and applying a second polygonal masking pattern comprises applying a first octagonal masking pattern and applying a second octagonal masking pattern.

19. The method of claim 10 wherein providing a starting stack comprises providing a stack of a first ferromagnetic layer and a second ferromagnetic layer separated by a non-magnetic spacer layer.

20. A method of making memory cells, the method comprising:
providing a starting stack having a first area;
masking a portion of the first area of the starting stack, resulting in a first masked portion;
masking a second portion of the first area of the starting stack, resulting in a second masked portion;
masking a third portion of the first area of the starting stack, resulting in a third masked portion;
wherein an intersection of the first masked portion and the second masked portion defines a first memory cell and an intersection of the second masked portion and the third masked portion defines a second memory cell.
